(19) United States
(12) Patent Application Publication
(10) Pub. No.: US 2024/0049408 A1
(43) Pub. Date: Feb. 8, 2024

(54) KEYBOARD MODULE

(71) Applicant: Primax Electronics Ltd., Taipei (TW)

(72) Inventors: Fang-Lung Yuan, Taipei (TW); Tsu-Yi Chen, Taipei (TW)

(21) Appl. No.: 17/945,445

(22) Filed: Sep. 15, 2022

(30) Foreign Application Priority Data
Aug. 3, 2022 (TW) 111129230

(51) Int. Cl. H05K 5/02

(52) U.S. Cl. CPC H05K 5/0215

(57) ABSTRACT

A keyboard module is provided, which includes a membrane circuit board, a base plate and a waterproof breathable film. The membrane circuit board has an air channel and at least one air hole communicating with the air channel and exposed from a lower surface of the membrane circuit board. The base plate is disposed beneath the membrane circuit board, in which the base plate has a first opening through the base plate and communicating with the air hole. The waterproof breathable film is disposed beneath the base plate and covers the first opening.

### FIELD OF THE INVENTION

The present disclosure relates to a keyboard module.

### BACKGROUND OF THE INVENTION

Generally, in order to prevent external moisture or liquid from entering a membrane switch circuit and thus causing a short circuit, the membrane switch circuit is designed to be a sealed structure so that it has a waterproof function. However, there is internal gas in the sealed membrane switch circuit. When a temperature rises, a volume of the internal gas expands, which makes key contacts of the membrane switch circuit difficult to conduct; when a temperature decreases, a volume of the internal gas shrinks, which makes the key contacts of the membrane switch circuit easy to be in contact with each other and thus conduct. Therefore, air channels are currently provided in some membrane switch circuits to prevent the volume change of the internal gas caused by the temperature from affecting the conduction of the membrane switch circuits. However, moisture easily enters along the air channel, which reduces waterproof performance of the membrane switch circuit.

### SUMMARY OF THE INVENTION

The present disclosure provides a keyboard module, which includes a membrane circuit board, a base plate and a waterproof breathable film. The membrane circuit board has an air channel and at least one air hole communicating with the air channel and exposed from a lower surface of the membrane circuit board. The base plate is disposed beneath the membrane circuit board, in which the base plate has a first opening through the base plate and communicating with the air hole. The waterproof breathable film is disposed beneath the base plate and covers the first opening.

In some embodiments of the present disclosure, the membrane circuit board has an upper membrane and a lower membrane, and the air channel is between the upper membrane and the lower membrane, and the lower membrane has the air hole through the lower membrane.

In some embodiments of the present disclosure, the first opening is substantially aligned with the air hole.

In some embodiments of the present disclosure, the keyboard module further includes an adhesive layer disposed between the membrane circuit board and the base plate, in which the adhesive layer has a second opening through the adhesive layer, and the second opening communicates with the air hole.

In some embodiments of the present disclosure, the keyboard module further includes a lower element disposed beneath the base plate, in which the lower element has a third opening through the lower element and communicating with the first opening, and the waterproof breathable film is disposed beneath the lower element and covers the third opening.

In some embodiments of the present disclosure, a vertical projection of the third opening is overlapped with a vertical projection of the first opening.

In some embodiments of the present disclosure, the third opening is substantially aligned with the first opening.

In some embodiments of the present disclosure, the waterproof breathable film is adhered to a lower surface of the lower element.

In some embodiments of the present disclosure, the lower element includes a backlight module or at least one Mylar sheet.

In some embodiments of the present disclosure, the waterproof breathable film is adhered to a lower surface of the backlight module or a lower surface of the Mylar sheet.

### BRIEF DESCRIPTION OF THE DRAWINGS

Aspects of the present disclosure are best understood from the following embodiments, read in conjunction with the accompanying drawings. It should be understood, however, that in accordance with common practice in the industry, various features have not necessarily been drawn to scale. Indeed, shapes of the various features may be suitably adjusted for clarity, and dimensions of the various features may be arbitrarily increased or decreased.

FIG. 1 is a schematic cross-sectional view of a keyboard module according to an embodiment of the present disclosure.

FIG. 2 is a schematic cross-sectional view of a keyboard module according to an embodiment of the present disclosure.

FIG. 3 is a schematic cross-sectional view of a keyboard module according to an embodiment of the present disclosure.

### DETAIL DESCRIPTION OF THE PREFERRED EMBODIMENT

The advantages and features of the present disclosure and the method for achieving the same will be described in more detail with reference to exemplary embodiments and the accompanying drawings to make it easier to understand. However, the present disclosure can be implemented in different forms and should not be construed as being limited to the embodiments set forth herein. On the contrary, for those skilled in the art, the provided embodiments will make this disclosure more thorough, comprehensive and complete to convey the scope of the present disclosure.

The spatially relative terms in the text, such as “beneath” and “over”, are used to facilitate the description of the relative relationship between one element or feature and another element or feature in the drawings. The true meaning of the spatially relative terms includes other orientations. For example, when the drawing is flipped up and down by 180 degrees, the relationship between the one element and the other element may change from “beneath” to “over.” In addition, the spatially relative descriptions used herein should be interpreted the same.

As described in the related art, moisture easily enters along the air channel, which reduces waterproof performance of the membrane switch circuit. Accordingly, the present disclosure provides a keyboard module including a waterproof breathable film to solve aforementioned issues. Various embodiments of the keyboard module of the present disclosure will be described in detail below.

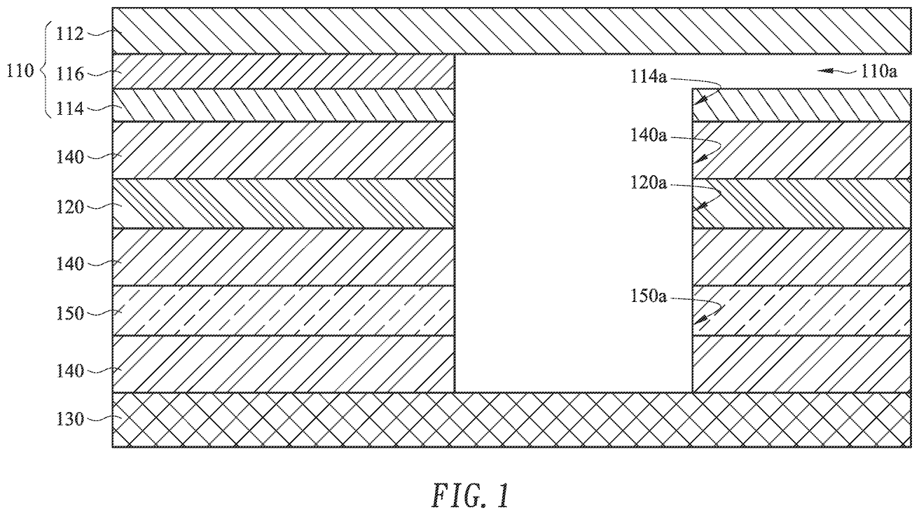

FIG. 1 is a schematic cross-sectional view of a keyboard module according to an embodiment of the present disclosure. As shown in FIG. 1, the keyboard module includes a membrane circuit board 110, a base plate 120 and a waterproof breathable film 130.

In some embodiments, the membrane circuit board 110 has an upper membrane 112 and a lower membrane 114 that are substantially parallel to each other. In some embodiments, the membrane circuit board 110 further has a spacer layer 116 sandwiched between the upper membrane 112 and the lower membrane 114. The upper membrane 112, the lower membrane 114 and the spacer layer 116 can be made of plastic, such as polycarbonate (PC), polyethylene terephthalate (PET), polymethyl methacrylate (PMMA), polyurethane (PU) or polyimide (PI). In some embodiments, the spacer layer 116 has a through hole (not shown), and a lower surface of the upper membrane 112 is provided with an upper trigger portion (not shown), and an upper surface of the lower membrane 114 is provided with a lower trigger portion (not shown). When a user presses the key, the upper membrane 112 is pressed and deforms (e.g., protrudes downward), so that the upper trigger portion is in contact with the lower trigger portion, and the upper trigger portion and the lower trigger portion are conducted. However, the present disclosure is not limited to the above embodiments, and in other embodiments, the membrane circuit board may have three or more layers of membranes or may have other kinds of trigger structures.

Please refer to FIG. 1, the membrane circuit board 110 has an air channel 110a and at least one air hole 114a, and the air channel 110a can communicate with the above-mentioned through hole, so as to prevent gas located in the through hole from affecting conduction between the two trigger portions (e.g., the above-mentioned upper and lower trigger portions). The air hole 114a communicates with the air channel 110a and is exposed from a lower surface of the membrane circuit board 110. In some embodiments, the air channel 110a is located between the upper membrane 112 and the lower membrane 114, and the lower membrane 114 has the air hole 114a through the lower membrane 114. In some embodiments, the position of the air channel 110a is defined by arrangement of the spacer layer 116 and/or a waterproof glue (not shown). In some embodiments, an end portion of the air channel 110a may have a serpentine shape in a top view. In some embodiments, the air hole 114a is connected to an end of the end portion of the air channel 110a (please refer to FIG. 1), but the present disclosure is not limited thereto. In other embodiments, the air hole 114a may be connected to another position of the air channel 110a.

The base plate 120 is disposed beneath the membrane circuit board 110. The base plate 120 has a first opening 120a through the base plate 120 and communicates with the air hole 114a. In some embodiments, a vertical projection of the first opening 120a is overlapped with a vertical projection of the air hole 114a. In some embodiments, the first opening 120a is generally aligned with the air hole 114a. In this specification, the term “substantially aligned” means that projections of two elements along a vertical direction (i.e., along a thickness direction of the element) are completely overlapped or nearly completely overlapped with each other.

The waterproof breathable film 130 is disposed beneath the base plate 120 and covers the first opening 120a to effectively prevent moisture from entering along the air hole 114a and the air channel 110a and then contacting an internal structure of the membrane circuit board 110, so waterproof performance of the keyboard module can be significantly improved. In some embodiments, the waterproof breathable film 130 is an acoustic mesh, which has good waterproofness and breathability simultaneously. In some embodiments, the waterproof breathable film 130 is monofilament polyester fabrics, and diameter, type and mesh counts of the monofilament can be adjusted appropriately to meet actual requirements. In some embodiments, an open area of the waterproof breathable film 130 is in a range of from 10% to 60%. In some embodiments, a pore size of the waterproof breathable film 130 is in a range of from 20 microns to 120 microns. However, the present disclosure is not limited to the above-mentioned embodiments, and the opening area and pore size of the waterproof breathable film 130 can be appropriately adjusted to meet actual requirements.

In some embodiments, the keyboard module further includes an adhesive layer 140 disposed between the membrane circuit board 110 and the base plate 120, so that the membrane circuit board 110 and the base plate 120 are adhered to each other. The adhesive layer 140 has a second opening 140a through the adhesive layer 140, and the second opening 140a communicates with the air hole 114a. In some embodiments, a vertical projection of the second opening 140a is overlapped with the vertical projection of the air hole 114a. In some embodiments, the second opening 140a is generally aligned with the air hole 114a.

In some embodiments, the keyboard module further includes a lower element 150 disposed beneath the base plate 120. In some embodiments, the lower element 150 is adhered to a lower surface of the base plate 120 through another adhesive layer 140. The lower element 150 has a third opening 150a through the lower element 150 and communicating with the first opening 120a, and the waterproof breathable film 130 is disposed beneath the lower element 150 and covers the third opening 150a. In some embodiments, a vertical projection of the third opening 150a is overlapped with the vertical projection of the first opening 120a. In some embodiments, the third opening 150a is substantially aligned with the first opening 120a.

In some embodiments, the waterproof breathable film 130 is adhered to a lower surface of the lower element 150 through another adhesive layer 140. In some embodiments, the lower element 150 includes a backlight module or at least one Mylar sheet. In some embodiments, the waterproof breathable film 130 is adhered to a lower surface of the backlight module or a lower surface of the Mylar sheet.

It is worth noting that since the air hole 114a of the lower membrane 114 of the membrane circuit board 110, the second opening 140a of the adhesive layer 140, the first opening 120a of the base plate 120, the opening (not marked) of the other adhesive layer 140, the third opening 150a of the lower element 150 and the opening (not marked) of the further adhesive layer 140 communicated with one another are provided, and the third opening 150a is covered with the waterproof breathable film 130, it can effectively prevent moisture from entering the lower element 150 and further prevent moisture from entering along the air hole 114a and the air channel 110a and then contacting the internal structure of the membrane circuit board 110, so that the waterproof performance of the keyboard module can be significantly improved.

However, the present disclosure is not limited to the above-mentioned embodiments, the arrangement position of the waterproof breathable film, the arrangement positions, dimensions and cross-sectional shapes (e.g., straight line-shaped, broken line-shaped, curved shaped or having another shape) of the air hole and the opening of each layer can be adjusted appropriately as long as the air channel can communicate with the waterproof breathable film. Various embodiments are provided below by way of illustration.

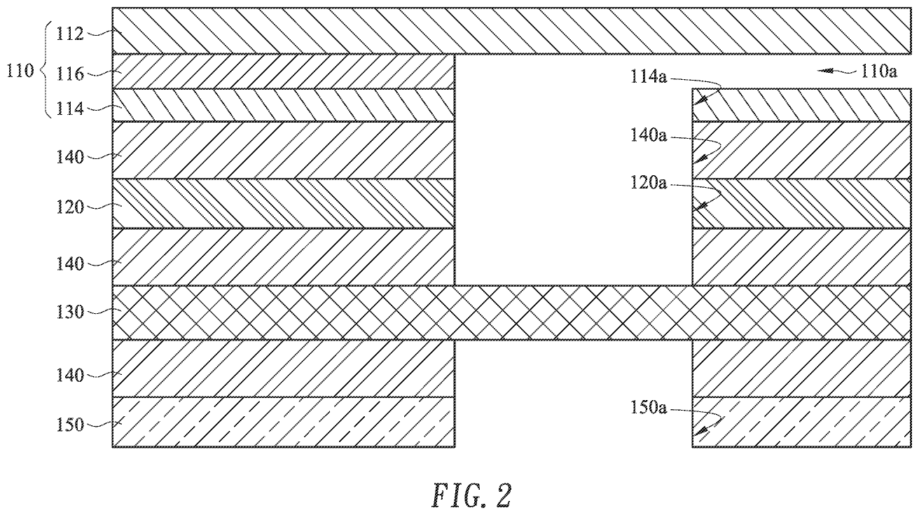

FIG. 2 is a schematic cross-sectional view of a keyboard module according to an embodiment of the present disclosure. The difference between FIG. 2 and FIG. 1 is that the waterproof breathable film 130 in FIG. 2 is disposed between the base plate 120 and the lower element 150, and the waterproof breathable film 130 is adhered to a lower surface of the base plate 120 and an upper surface of the lower element 150 through the two adhesive layers 140, respectively.

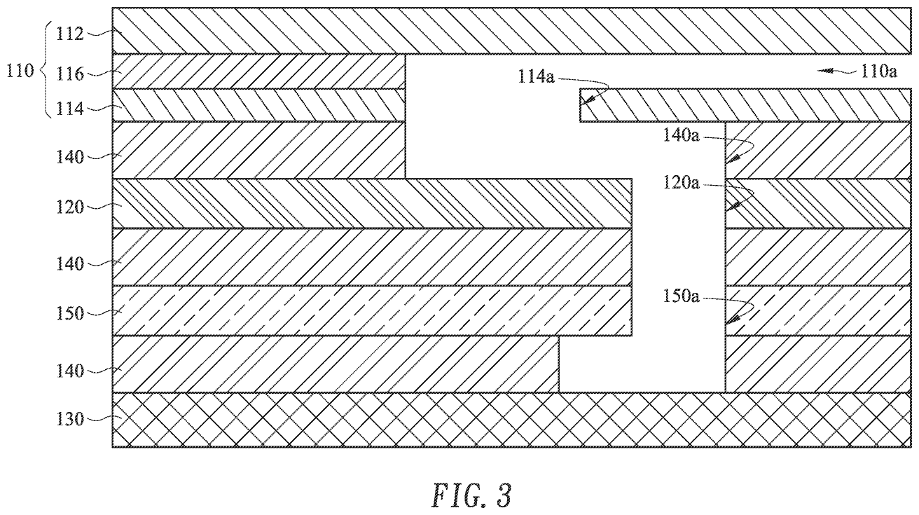

FIG. 3 is a schematic cross-sectional view of a keyboard module according to an embodiment of the present disclosure. The difference between FIG. 3 and FIG. 1 is that the arrangement positions of the air hole 114a, the second opening 140a, the first opening 120a, and the third opening 150a and their dimensions (e.g., widths) are slightly adjusted, so that a path communicating with the air channel 110a is longer.

However, the above are only the preferred embodiments of the present disclosure, and should not be used to limit the scope of implementation of the present disclosure, that is, simple equivalent changes and modifications made in accordance with claims and description of the present disclosure are still within the scope of the present disclosure. In addition, any embodiment of the present disclosure or claim does not need to achieve all the objectives or advantages disclosed in the present disclosure. In addition, the abstract and the title are not used to limit the scope of claims of the present disclosure.

What is claimed is:

1. A keyboard module, comprising:
a membrane circuit board, having an air channel and at least one air hole connected to the air channel and exposed from a lower surface of the membrane circuit board;
a base plate disposed beneath the membrane circuit board, wherein the base plate has a first opening through the base plate and communicating with the air hole; and
a waterproof breathable film disposed beneath the base plate and covering the first opening.

2. The keyboard module of claim 1, wherein the membrane circuit board has an upper membrane and a lower membrane, and the air channel is between the upper membrane and the lower membrane, and the lower membrane has the air hole through the lower membrane.

3. The keyboard module of claim 1, wherein the first opening is substantially aligned with the air hole.

4. The keyboard module of claim 1, further comprising:
an adhesive layer disposed between the membrane circuit board and the base plate, wherein the adhesive layer has a second opening through the adhesive layer, and the second opening communicates with the air hole.

5. The keyboard module of claim 1, further comprising:
a lower element disposed beneath the base plate, wherein the lower element has a third opening through the lower element and communicating with the first opening, and the waterproof breathable film is disposed beneath the lower element and covers the third opening.

6. The keyboard module of claim 5, wherein a vertical projection of the third opening is overlapped with a vertical projection of the first opening.

7. The keyboard module of claim 5, wherein the third opening is substantially aligned with the first opening.

8. The keyboard module of claim 5, wherein the waterproof breathable film is adhered to a lower surface of the lower element.

9. The keyboard module of claim 5, wherein the lower element comprises a backlight module or at least one Mylar sheet.

10. The keyboard module of claim 9, wherein the waterproof breathable film is adhered to a lower surface of the backlight module or a lower surface of the Mylar sheet.
